(19) United States
(12) Patent Application Publication
(10) Pub. No.: US 2021/0235060 A1
(43) Pub. Date: Jul. 29, 2021

(54) SOLID-STATE IMAGING DEVICE, INFORMATION PROCESSING DEVICE, INFORMATION PROCESSING METHOD, AND CALIBRATION METHOD

(71) Applicant: SONY CORPORATION, TOKYO (JP)

(72) Inventors: YASUTAKA HIRASAWA, TOKYO (JP); YING LU, TOKYO (JP)

(21) Appl. No.: 17/055,790

(22) PCT Filed: Feb. 18, 2019
(86) PCT No.: PCT/JP2019/005778

§ 371 Date: Nov. 16, 2020

(30) Foreign Application Priority Data
May 18, 2018 (JP) 2018-096043

(51) Int. Cl. H04N 13/218; H04N 13/246; H04N 5/369; H04N 13/254; H01L 27/146

(52) U.S. Cl. CPC H04N 13/218; H04N 13/246; H04N 2013/0081; H04N 13/254; H01L 27/14627; H04N 5/3696

(57) ABSTRACT

A polarization imaging unit 20 has a configuration in which each pixel group including a plurality of pixels is provided with a microlens and the pixel group includes at least three polarization pixels having different polarization directions, and the pixels included in the pixel group perform photoelectric conversion of light that is incident via the microlenses to acquire a polarization image. A polarization state calculation unit 31 of an information processing unit 30 accurately acquires a polarization state of an object by using a polarization image of the object acquired using the polarization imaging unit 20 and a main lens 15, and a correction parameter stored in advance in a correction parameter storage unit 32 and set for each microlens in accordance with the main lens.

### TECHNICAL FIELD

This technology relates to a solid-state imaging device, an information processing device, an information processing method, and a calibration method, and allows for accurate acquisition of a polarization state.

### BACKGROUND ART

In recent years, acquisition of a three-dimensional shape of an object has been performed, and an active method or a passive method is used for such acquisition of a three-dimensional shape. In the active method, energy such as light is radiated, and three-dimensional measurement is performed on the basis of an amount of energy reflected from an object. Thus, an energy radiation unit is required to radiate energy. Moreover, the active method causes an increase in cost and power consumption for energy radiation, and cannot be used easily. In contrast to the active method, the passive method uses features of an image for measurement, does not require an energy radiation unit, and does not causes an increase in cost and power consumption for energy radiation. When the passive method is used to acquire a three-dimensional shape, for example, a stereo camera is used to generate a depth map. Furthermore, polarization imaging, in which polarization images having a plurality of polarization directions are acquired to generate a normal map, or the like is also performed.

In the acquisition of polarization images, it is possible to acquire polarization images having a plurality of polarization directions by capturing images with a polarization plate arranged in front of an imaging unit and the polarization plate rotated about an axis that is in a direction of an optical axis of the imaging unit. Furthermore, Patent Document 1 describes that polarizers having different polarization directions are arranged one in each pixel of an imaging unit so that polarization images having a plurality of polarization directions can be acquired by one image capturing.

### CITATION LIST

### Patent Document

Patent Document 1: Japanese Patent Application Laid-Open No. 2009-055624

### SUMMARY OF THE INVENTION

### Problems to be Solved by the Invention

Incidentally, in the method in which polarizers having different polarization directions are arranged one in each pixel of the imaging unit, a plurality of pixels at different positions is used for each polarization direction to generate polarization images having a plurality of polarization directions. The pixels at different positions correspond to different positions on an object, and there is a possibility that a polarization state may be obtained with a lower accuracy in cases of an object having a shape that changes rapidly, an object having a textured surface, an edge of an object, and the like.

It is therefore an object of this technology to provide a solid-state imaging device, an information processing device, an information processing method, and a calibration method that allow for accurate acquisition of a polarization state.

### Solutions to Problems

A first aspect of this technology provides

a solid-state imaging device in which

each pixel group including a plurality of pixels is provided with a microlens,

the pixel group includes at least three polarization pixels having different polarization directions, and

the pixels included in the pixel group perform photoelectric conversion of light incident via the microlens.

This technology provides a configuration in which each pixel group including a plurality of pixels is provided with a microlens, and the pixel group includes at least three polarization pixels having different polarization directions. Furthermore, in the configuration, the pixel group may include two pixels having the same polarization direction. In a case where the pixel group includes pixels in a two-dimensional area of two by two pixels, the pixel group is constituted by a polarization pixel having a polarization direction at a specific angle, a polarization image having a polarization direction with an angular difference of 45 degrees from the specific angle, and two non-polarization pixels. In a case where the pixel group includes pixels in a two-dimensional area of n by n pixels (n is a natural number equal to or higher than 3), polarization pixels that are one pixel away from each other have the same polarization direction. Furthermore, in the configuration, every one of the pixel groups may be provided with a color filter, and color filters of adjacent pixel groups may differ in wavelength of light that is allowed to pass through. The pixels included in the pixel group perform photoelectric conversion of light that is incident via the microlens to generate a monochrome polarization image or a color polarization image.

A second aspect of this technology provides

an information processing device including

a polarization state calculation unit that calculates a polarization state of an object by using a polarization image of the object acquired by using a main lens and a solid-state imaging device provided with a microlens for each pixel group including at least three polarization pixels having different polarization directions, and a correction parameter set in advance for each microlens in accordance with the main lens.

In this technology, the polarization state calculation unit calculates a polarization state of an object by using a polarization image of the object acquired by using a main lens and a solid-state imaging device provided with a microlens for each pixel group including at least three polarization pixels having different polarization directions, and a correction parameter set in advance for each microlens in accordance with the main lens. Furthermore, the pixel group may include two pixels having the same polarization direction. One viewpoint image may be generated using one of the pixels having the same polarization direction in every one of the pixel groups, and another viewpoint image may be generated using another of the pixels, so that a depth information generation unit may generate depth information indicating a distance to the object on the basis of the one viewpoint image and the another viewpoint image. A normal information generation unit may generate normal information indicating a normal to the object on the basis of the calculated polarization state of the object. Moreover, when depth information and normal information are generated, on the basis of the generated depth information and normal information, an information integration unit may generate accurate depth information.

A third aspect of this technology provides

an information processing method including

calculating, by a polarization state calculation unit, a polarization state of an object, by using a polarization image of the object acquired by using a main lens and a solid-state imaging device provided with a microlens for each pixel group including at least three polarization pixels having different polarization directions, and a correction parameter set in advance for each microlens in accordance with the main lens.

A fourth aspect of this technology provides

a calibration method including

generating, by a correction parameter generation unit, a correction parameter for correcting a polarization state of a light source calculated on the basis of a polarization image obtained by imaging the light source in a known polarization state by using a main lens and a solid-state imaging device provided with a microlens for each pixel group including at least three polarization pixels having different polarization directions, to the known polarization state of the light source.

In this technology, the correction parameter generation unit controls switching of the polarization state of the light source and imaging of the solid-state imaging device to cause the solid-state imaging device to acquire a polarization image for every one of a plurality of the polarization states. The solid-state imaging device has a configuration in which each pixel group including at least three polarization pixels having different polarization directions is provided with a microlens, and a main lens is used to image a light source in a known polarization state and acquire a polarization image. The correction parameter generation unit generates a correction parameter for correcting a polarization state of the light source calculated on the basis of the acquired polarization image to the known polarization state of the light source.

### Effects of the Invention

According to this technology, the solid-state imaging device has a configuration in which each pixel group including a plurality of pixels is provided with a microlens and the pixel group includes at least three polarization pixels having different polarization directions, and the pixels included in the pixel group perform photoelectric conversion of light that is incident via the microlenses. Furthermore, the information processing device uses a polarization image of an object acquired using the solid-state imaging device and a main lens, and a correction parameter set in advance for each microlens in accordance with the main lens, to calculate a polarization state of the object. Thus, a polarization state can be acquired accurately. Note that effects described herein are merely illustrative and are not intended to be restrictive, and there may be additional effects.

### BRIEF DESCRIPTION OF DRAWINGS

FIG. 1 is a diagram illustrating a configuration of a system.

FIG. 2 is a diagram for describing a relationship between a polarization image and an observation target.

FIG. 3 is a diagram illustrating a relationship between luminance and a polarization angle.

FIG. 4 is a diagram illustrating a part of a pixel structure of a polarization imaging unit.

FIG. 5 is a diagram illustrating another pixel arrangement of the polarization imaging unit.

FIG. 6 is a diagram for describing operation of the polarization imaging unit.

FIG. 7 is a diagram illustrating a position where light incident on each pixel has passed through.

FIG. 8 is a flowchart illustrating operation of a first embodiment of an information processing unit.

FIG. 9 is a diagram illustrating a configuration of a calibration device that generates a correction parameter.

FIG. 10 is a diagram illustrating a pixel arrangement that includes a set of pixels having the same polarization characteristic.

FIG. 11 is a diagram illustrating a configuration of a second embodiment of the information processing unit.

FIG. 12 is a diagram for describing generation of a plurality of viewpoint images.

FIG. 13 is a flowchart illustrating operation of the second embodiment of the information processing unit.

FIG. 14 is a diagram illustrating a configuration of a third embodiment of the information processing unit.

FIG. 15 is a diagram illustrating a relationship between a polarization degree and a zenith angle.

FIG. 16 is a diagram for describing information integration processing.

FIG. 17 is a flowchart illustrating operation of the third embodiment of the information processing unit.

### MODE FOR CARRYING OUT THE INVENTION

Modes for carrying out the present technology will be described below. Note that the description will be made in the order below.

1. Configuration of system

2. Configuration and operation of polarization imaging unit

3. Configuration and operation of information processing unit

3-1. First embodiment of information processing unit

3-2. Generation of correction parameter

3-3. Second embodiment of information processing unit

3-4. Third embodiment of information processing unit

3-5. Other embodiments of information processing unit

4. Application examples

### 1. Configuration of System

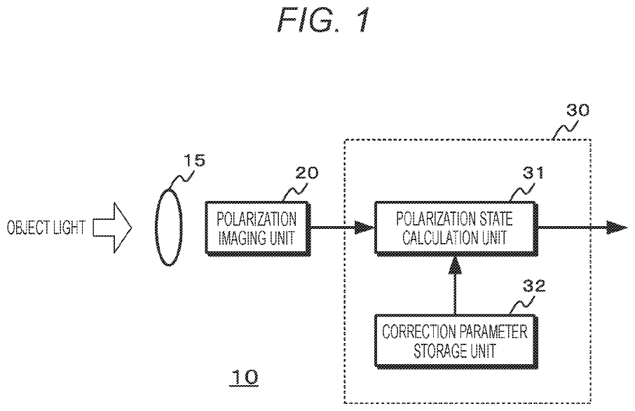

FIG. 1 illustrates a configuration of a system using a solid-state imaging device and an information processing device of the present technology. A system 10 includes a main lens 15, a polarization imaging unit 20, and an information processing unit 30. Note that the polarization imaging unit 20 corresponds to the solid-state imaging device of the present technology, and the information processing unit 30 corresponds to the information processing device of the present technology.

The polarization imaging unit 20 uses the main lens 15 to capture an image of an object, acquires polarization images having a plurality of polarization directions, and outputs the polarization images to the information processing unit 30. The information processing unit 30 calculates a polarization state of the object using the polarization images acquired by the polarization imaging unit 20 and a correction parameter set in advance for each microlens in accordance with the main lens 15.

### 2. Configuration and Operation of Polarization Imaging Unit

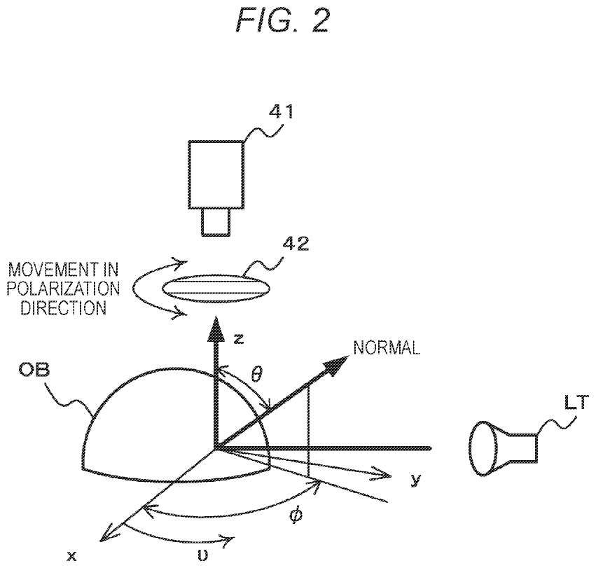

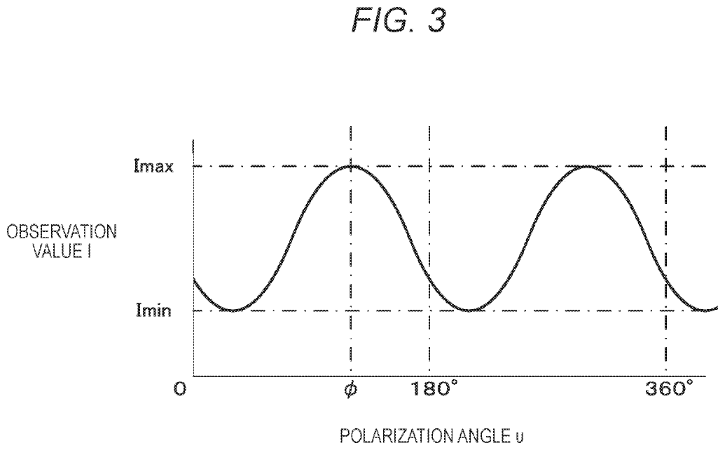

Here, a relationship between a polarization image and an observation target will be described. As illustrated in FIG. 2, for example, an object OB is illuminated with a light source LT, and an imaging unit 41 captures images of the object OB via a polarization plate 42. In this case, the captured images vary in luminance of the object OB in accordance with a polarization direction of the polarization plate 42. Note that the highest luminance is expressed as Imax, and the lowest luminance is expressed as Imin. Furthermore, assuming that an x-axis and a y-axis of a two-dimensional coordinate are on a plane of the polarization plate 42, the polarization direction of the polarization plate 42 is expressed as a polarization angle U, which is an angle in the y-axis direction with respect to the x-axis. The polarization direction of the polarization plate 42 has a cycle of 180 degrees, and a rotation of 180 degrees returns the polarization state to the original state. Furthermore, the polarization angle U at which the maximum luminance Imax is observed is expressed as an azimuth angle cp. With such definitions, a luminance I observed when the polarization direction of the polarization plate 42 is tentatively changed can be given by a polarization model equation of Equation (1). That is, the polarization state of the object OB can be calculated. Note that FIG. 3 illustrates a relationship between the luminance and the polarization angle.

$$\begin{matrix}[ Math . 1 ] & \\ I = \frac{{I}_{max} + {I}_{min}}{2} + \frac{{I}_{max} - {I}_{min}}{2} cos 2 ( υ - ∅ ) & ( 1 )\end{matrix}$$

The polarization imaging unit 20 has a configuration in which each pixel group including a plurality of pixels is provided with a microlens, and the pixel group includes at least three polarization pixels having different polarization directions. The pixels included in each pixel group perform photoelectric conversion of light that is incident via the microlens, and this allows for accurate calculation of a polarization state of an object.

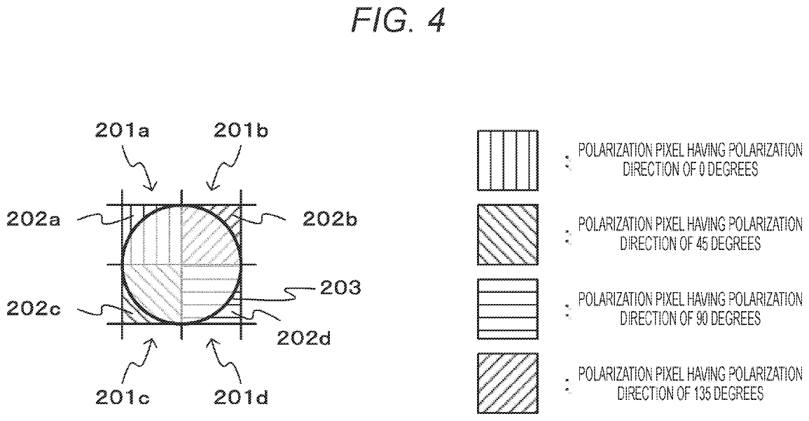

FIG. 4 illustrates a part of a pixel structure of the polarization imaging unit 20. The pixels of the polarization imaging unit 20 constitute, for example, pixel groups each including two by two pixels, and polarizers 202a to 202d are respectively arranged on incident surfaces of pixels 201a to 201d constituting one pixel group. The polarizers 202a to 202d are, for example, wire grid polarizers or the like. The polarizers in the corresponding pixels have different polarization directions. For example, the polarizer 202a provided in the pixel 201a allows 0-degree polarized light to pass through. Furthermore, the polarizer 202b in the pixel 201b allows 135-degree polarized light to pass through, the polarizer 202c in the pixel 201c allows 45-degree polarized light to pass through, and the polarizer 202d in the pixel 201d allows 90-degree polarized light to pass through. That is, the pixel 201a is a polarization pixel having a polarization direction of 0 degrees that outputs an observation value (pixel value or luminance value) in accordance with 0-degree polarized light, and the pixel 201b is a polarization pixel having a polarization direction of 135 degrees that outputs an observation value in accordance with 135-degree polarized light. Furthermore, the pixel 201c is a polarization pixel having a polarization direction of 45 degrees that outputs an observation value in accordance with 45-degree polarized light, and the pixel 201d is a polarization pixel having a polarization direction of 90 degrees that outputs an observation value in accordance with 90-degree polarized light.

Providing a polarizer on an incident surface side of a pixel and providing pixel groups each including polarization pixels having four polarization directions in this way makes it possible to obtain an observation value for each polarization direction, and calculate a polarization state for each pixel group. Furthermore, it is possible to calculate a polarization state for each pixel by performing interpolation processing in which observation values of polarization pixels having the same polarization direction are used to calculate an observation value of a position of a polarization pixel having another polarization direction.

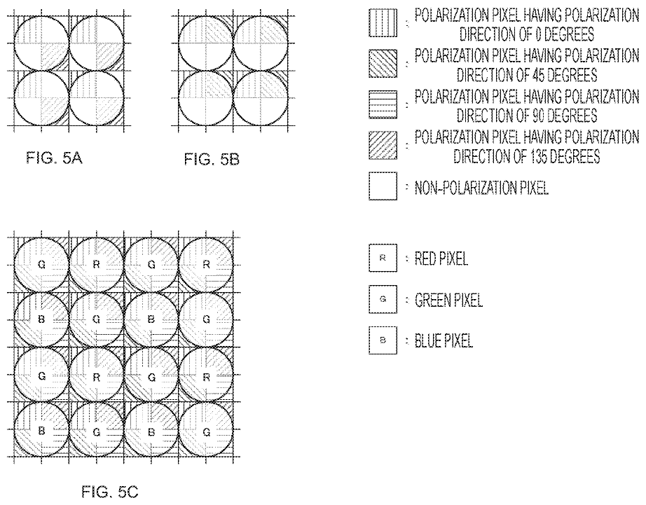

A microlens 203 is arranged for each pixel group, and light that has passed through the microlens 203 is incident on each pixel of the pixel group. Note that the microlens 203 is only required to be provided one for each pixel group including a plurality of pixels, and the pixel group is not limited to pixels in a two-dimensional area of two by two pixels. Furthermore, FIG. 4 illustrates a case where each of the polarizers allows 0-degree, 45-degree, 90-degree, or 135-degree polarized light to pass through, but the angles may be any other angles as long as the configuration allows for calculation of a polarization state, that is, the angles are in three different polarization directions (the polarization directions may include non-polarization). FIG. 5 illustrates another pixel arrangement of the polarization imaging unit. (a) and (b) of FIG. 5 illustrate cases where a pixel group is constituted by two polarization pixels having polarization directions that differ in angle by 45 degrees or 135 degrees and two non-polarization pixels. Furthermore, the polarization imaging unit 20 may acquire a color polarization image, and (c) of FIG. 5 illustrates a pixel arrangement in a case where a red polarization image, a green polarization image, and a blue polarization image are acquired. In a case where a color polarization image is acquired, color filters are provided so that adjacent pixel groups may differ in wavelength of light that is allowed to pass through. Note that (c) of FIG. 5 illustrates a case of a Bayer color array with a pixel group serving as one color unit.

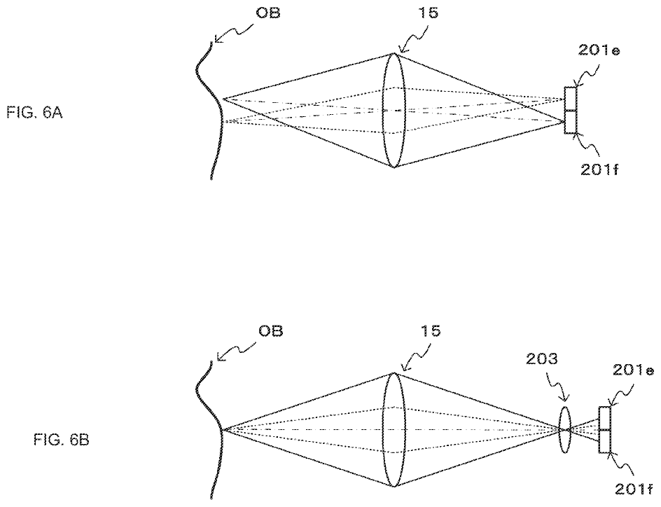

FIG. 6 is a diagram for describing operation of the polarization imaging unit. (a) of FIG. 6 illustrates an optical path of a conventional polarization imaging unit without a microlens, and (b) of FIG. 6 illustrates an optical path of the polarization imaging unit of the present technology using a microlens.

Light from an object OB is condensed by the main lens 15 and is incident on the polarization imaging unit 20. Note that FIG. 6 illustrates a polarization pixel 201e having a first polarization direction and a polarization pixel 201f having a second polarization direction different from the first direction.

In a conventional configuration illustrated in (a) of FIG. 6, a focal plane of the main lens 15 is at an imaging surface (sensor surface) of the polarization imaging unit 20, and this causes light incident on the polarization pixel 201e and light incident on the polarization pixel 201f to indicate different positions of the object OB. Thus, in a case where observation values of the polarization pixel 201e and the polarization pixel 201f are used, the polarization state of the object cannot be calculated accurately.

In a configuration of the present technology illustrated in (b) of FIG. 6, each pixel group is provided with the microlens 203, and the position of the microlens 203 is at the position of the focal plane of the main lens 15. In this case, light from a desired position on the object OB that has passed through an upper side of the main lens 15 is condensed and incident on the polarization pixel 201f via the microlens 203. Furthermore, light from the desired position on the object OB that has passed through a lower side of the main lens 15 is condensed and incident on the polarization pixel 201e via the microlens 203. That is, the polarization imaging unit 20 performs an operation similar to that of a so-called light-field camera, and observation values of the polarization pixel 201e and the polarization pixel 201f indicate a polarization state of the desired position on the object OB. Thus, it becomes possible to calculate a polarization state of an object more accurately than before by using observation values of the polarization pixel 201e and the polarization pixel 201f.

### 3. Configuration and Operation of Information Processing Unit

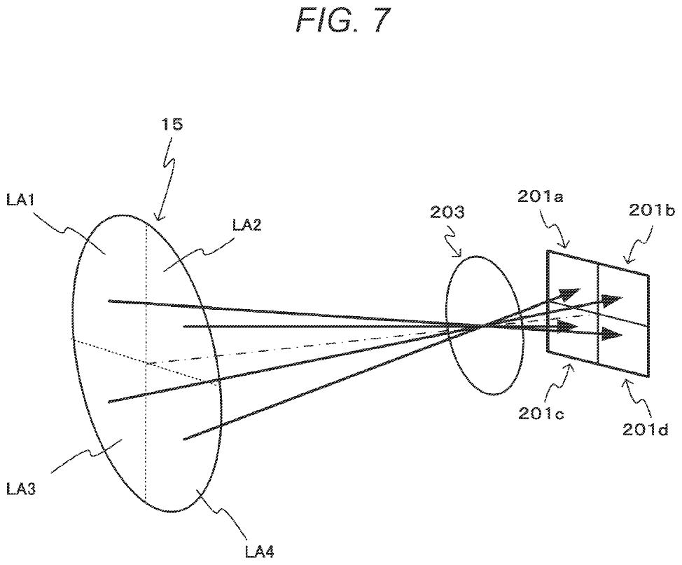

Next, a configuration and operation of an information processing unit will be described. In a case of a pixel group provided with a microlens, as illustrated in (b) of FIG. 6, light incident on the pixels in the pixel group is light that has passed through a portion, which differs from pixel to pixel, in the main lens 15 and condensed. FIG. 7 illustrates a position where light incident on each pixel has passed through in a case of a pixel group of two by two pixels provided with the microlens 203. For example, light that has passed through a lower-right quarter area LA4 in the main lens 15 is condensed and incident on the pixel 201a. Furthermore, light that has passed through a lower-left quarter area LA3 in the main lens 15 is condensed and incident on the pixel 201b, light that has passed through an upper-right quarter area LA2 in the main lens 15 is condensed and incident on the pixel 201c, and light that has passed through an upper-left quarter area LA1 in the main lens 15 is condensed and incident on the pixel 201d. In this way, pieces of light incident on the corresponding pixels have passed through different areas of the main lens, and there is a possibility that the polarization state changes in accordance with a difference in path of the light. Thus, the information processing unit 30 corrects a change in polarization state caused by the main lens 15 and calculates a polarization state of an object more accurately than before.

<3-1. First Embodiment of Information Processing Unit>

An information processing unit 30 includes a polarization state calculation unit 31 and a correction parameter storage unit 32 as illustrated in FIG. 1. The polarization state calculation unit 31 calculates a polarization state of an object on the basis of polarization images having a plurality of polarization directions acquired by a polarization imaging unit 20. Furthermore, the polarization state calculation unit 31 uses a correction parameter stored in the correction parameter storage unit 32 to correct a change in polarization state caused by a lens in the polarization images, and calculates a polarization state of the object.

The polarization state calculation unit 31 calculates a Stokes vector S indicating a polarization state as the calculation of the polarization state. Here, when an observation value of a polarization pixel having a polarization direction of 0 degrees is expressed as I₀, an observation value of a polarization pixel having a polarization direction of 45 degrees is expressed as I₄₅, an observation value of a polarization pixel having a polarization direction of 90 degrees is expressed as I₉₀, and an observation value of a polarization pixel having a polarization direction of 135 degrees is expressed as Ins, a relationship between the Stokes vector and the observation values is given by Equation (2).

$$\begin{matrix}[ Math . 2 ] & \\ S = [ \begin{matrix}{S}_{0} \\ {S}_{1} \\ {S}_{2}\end{matrix} ] = [ \begin{matrix}\frac{{I}_{0} + {I}_{45} + {I}_{90} + {I}_{135}}{4} \\ {I}_{0} - {I}_{90} \\ {I}_{45} - {I}_{135}\end{matrix} ] & ( 2 )\end{matrix}$$

In the Stokes vector S, a component so indicates luminance or average luminance of non-polarization. Furthermore, a component Si indicates a difference between the observation values of the polarization directions of 0 degrees and 90 degrees, and a component s₂ indicates a difference between the observation values of the polarization directions of 45 degrees and 135 degrees.

Incidentally, as illustrated in (b) of FIG. 6, pieces of light incident on the corresponding pixels of a pixel group have passed through different portions of a main lens 15. FIG. 7 illustrates a position in a main lens where light incident on each pixel of a pixel group has passed through. For example, light that has passed through a lower-right quarter area LA4 in the main lens 15 is incident on a pixel 201a. Furthermore, light that has passed through a lower-left quarter area LA3 in the main lens 15 is incident on a pixel 201b, light that has passed through an upper-right quarter area LA2 in the main lens 15 is incident on a pixel 201c, and light that has passed through an upper-left quarter area LA1 in the main lens 15 is incident on a pixel 201d. In this way, pieces of light incident on the corresponding pixels have passed through different areas of the main lens, and there is a possibility that the polarization state changes differently due to a difference in path of the incident light. Thus, the polarization state calculation unit 31 acquires a correction parameter for each microlens from the correction parameter storage unit 32, and uses the acquired correction parameter to calculate a Stokes vector S. Equation (3) represents an equation for calculating a polarization state. The polarization state calculation unit 31 calculates a Stokes vector S at an object position indicated by the pixels of the pixel group by using observation values I₀, I₄₅, I₉₀, and Ins of the corresponding pixels of the pixel group provided with a microlens 203, and a correction parameter P set in advance for each microlens in accordance with the main lens 15. Note that details of the correction parameter will be described later.

$$\begin{matrix}[ Math . 3 ] & \\ [ \begin{matrix}{S}_{0} \\ {S}_{1} \\ {S}_{2}\end{matrix} ] = P [ \begin{matrix}{I}_{0} \\ {I}_{45} \\ {I}_{90} \\ {I}_{135}\end{matrix} ] & ( 3 )\end{matrix}$$

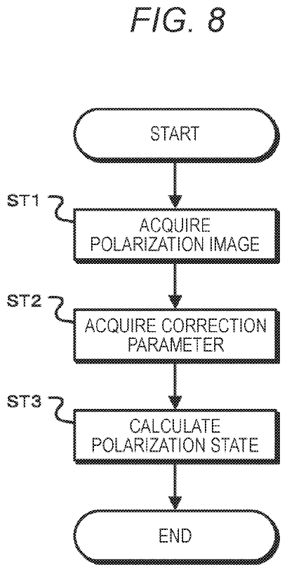

FIG. 8 is a flowchart illustrating operation of a first embodiment of the information processing unit. In step ST1, the information processing unit acquires a polarization image. The information processing unit 30 acquires a polarization image obtained by imaging a desired object with the polarization imaging unit 20 using the main lens 15, and the operation proceeds to step ST2.

In step ST2, the information processing unit acquires a correction parameter. The polarization state calculation unit 31 of the information processing unit 30 acquires, from the correction parameter storage unit 32, a correction parameter for each microlens 203 in accordance with the main lens 15, and the operation proceeds to step ST3.

In step ST3, the information processing unit calculates a polarization state. The polarization state calculation unit 31 calculates a Stokes vector S by computing Equation (3) using an observation value of each pixel of a pixel group and the correction parameter corresponding to the microlens of the pixel group.

In this way, according to the first embodiment of the information processing unit, a change in polarization state that occurs in the main lens is corrected, and a polarization state of an object can be calculated more accurately than before.

<3-2. Generation of Correction Parameter>

Next, generation of a correction parameter will be described.

In a case where a polarized illumination unit that emits linearly polarized light with a Stokes vector S as illumination light is imaged by the polarization imaging unit 20 using the main lens 15, a relationship between the Stokes vector S and observation values of corresponding pixels of a polarization image is given by Equation (4).

$$\begin{matrix}[ Math . 4 ] & \\ [ \begin{matrix}{S}_{0} \\ {S}_{1} \\ {S}_{2}\end{matrix} ] = [ \begin{matrix}0.25 & 0.25 & 0.25 & 0.25 \\ 1 & 0 & - 1 & 0 \\ 0 & 1 & 0 & - 1\end{matrix} ] [ \begin{matrix}{I}_{0} \\ {I}_{45} \\ {I}_{90} \\ {I}_{135}\end{matrix} ] & ( 4 )\end{matrix}$$

Furthermore, observation values generated by polarization pixels generally satisfy I₀+I₉₀=I₄₅+I₁₃₅, so Equation (4) can be converted to Equation (5). Furthermore, an inverse of a matrix A of Equation (5) is Equation (6).

$$\begin{matrix}[ Math . 5 ] & \\ [ \begin{matrix}{S}_{0} \\ {S}_{1} \\ {S}_{2} \\ 0\end{matrix} ] = [ \begin{matrix}0.25 & 0.25 & 0.25 & 0.25 \\ 1 & 0 & - 1 & 0 \\ 0 & 1 & 0 & - 1 \\ 1 & - 1 & 1 & - 1\end{matrix} ] [ \begin{matrix}{I}_{0} \\ {I}_{45} \\ {I}_{90} \\ {I}_{135}\end{matrix} ] = A [ \begin{matrix}{I}_{0} \\ {I}_{45} \\ {I}_{90} \\ {I}_{135}\end{matrix} ] & ( 5 ) \\ {A}^{- 1} = [ \begin{matrix}1.0 & 0.5 & 0.0 & 0.25 \\ 1.0 & 0.0 & 0.5 & - 0.25 \\ 1.0 & - 0.5 & 0 & 0.25 \\ 1.0 & 0.0 & - 0.5 & - 0.25\end{matrix} ] & ( 6 )\end{matrix}$$

A matrix B shown in Equation (7), which is obtained by removing the fourth column from Equation (6), can be used to calculate, on the basis of Equation (8), an observation value in a case where illumination light with the Stokes vector S is observed.

$$\begin{matrix}[ Math . 6 ] & \\ B = [ \begin{matrix}1.0 & 0.5 & 0.0 \\ 1.0 & 0.0 & 0.5 \\ 1.0 & - 0.5 & 0 \\ 1.0 & 0.0 & - 0.5\end{matrix} ] & ( 7 ) \\ [ \begin{matrix}{I}_{0} \\ {I}_{45} \\ {I}_{90} \\ {I}_{135}\end{matrix} ] = B [ \begin{matrix}{S}_{0} \\ {S}_{1} \\ {S}_{2}\end{matrix} ] & ( 8 )\end{matrix}$$

Furthermore, in a case where illumination light with a Stokes vector S passes through a lens, when the illumination light that has passed through the lens is expressed as a Stokes vector S′=[s₀, s₁, s₂]^{T}, then a relationship between the Stokes vector S before the illumination light passes through the lens and the Stokes vector S′=[s₀′, s₁′, s₂′]^{T} after the illumination light has passed through the lens is given by Equation (9). Note that a matrix M of Equation (9) is a Mueller matrix and indicates a change in polarization state when the illumination light passes through the lens, and Equation (9) can be expressed as Equation (10).

$$\begin{matrix}[ Math . 7 ] & \\ {S}^{′} = MS & ( 9 ) \\ [ \begin{matrix}{S}_{0}^{′} \\ {S}_{1}^{′} \\ {S}_{2}^{′}\end{matrix} ] = [ \begin{matrix}{m}_{00} & {m}_{01} & {m}_{02} \\ {m}_{10} & {m}_{11} & {m}_{12} \\ {m}_{20} & {m}_{21} & {m}_{22}\end{matrix} ] [ \begin{matrix}{S}_{0} \\ {S}_{1} \\ {S}_{2}\end{matrix} ] & ( 10 )\end{matrix}$$

Thus, an observation value in a case where the illumination light with the Stokes vector S is observed by the polarization imaging unit 20 can be calculated on the basis of Equation (11).

$$\begin{matrix}[ Math . 8 ] & \\ [ \begin{matrix}{I}_{0} \\ {I}_{45} \\ {I}_{90} \\ {I}_{135}\end{matrix} ] = B [ \begin{matrix}{S}_{0}^{′} \\ {S}_{1}^{′} \\ {S}_{2}^{′}\end{matrix} ] = B [ \begin{matrix}{m}_{00} & {m}_{01} & {m}_{02} \\ {m}_{10} & {m}_{11} & {m}_{12} \\ {m}_{20} & {m}_{21} & {m}_{22}\end{matrix} ] [ \begin{matrix}{S}_{0} \\ {S}_{1} \\ {S}_{2}\end{matrix} ] = [ \begin{matrix}{m}_{00} + 0.5 {m}_{10} & {m}_{01} + 0.5 {m}_{11} & {m}_{02} + 0.5 {m}_{12} \\ {m}_{00} + 0.5 {m}_{20} & {m}_{01} + 0.5 {m}_{21} & {m}_{02} + 0.5 {m}_{22} \\ {m}_{00} - 0.5 {m}_{10} & {m}_{01} - 0.5 {m}_{11} & {m}_{02} - 0.5 {m}_{12} \\ {m}_{00} - 0.5 {m}_{20} & {m}_{01} - 0.5 {m}_{21} & {m}_{02} - 0.5 {m}_{22}\end{matrix} ] [ \begin{matrix}{S}_{0} \\ {S}_{1} \\ {S}_{2}\end{matrix} ] & ( 11 )\end{matrix}$$

Here, in a case where a microlens is provided for each pixel group of two by two pixels, pieces of light incident on the corresponding pixels have passed through different areas in the main lens 15, and different Mueller matrices correspond to the corresponding pixels. Here, a Mueller matrix corresponding to the upper-left lens area LA1 illustrated in FIG. 7 is expressed as M1, a Mueller matrix corresponding to the upper-right lens area LA2 is expressed as M2, a Mueller matrix corresponding to the lower-left lens area LA3 is expressed as M3, and a Mueller matrix corresponding to the lower-right lens area LA4 is expressed as M4. In this case, the observation values Iⁿ=[I₀ⁿ, I₄₅ⁿ, I₉₀ⁿ, I₁₃₅ⁿ] (n=1, 2, 3, or 4) of the corresponding polarization directions in a case where the light with the Stokes vector S passes through each portion of the lens are calculated using Equation (12).

[Math. 9]

Iⁿ=BMⁿS (n=1,2,3,4) (12)

However, as described above, the illumination light incident on the pixel 201a has passed through the lower-right quarter area LA4 of the lens. Moreover, the illumination light incident on the pixel 201b has passed through the lower-left quarter area LA3 of the lens, the illumination light incident on the pixel 201c has passed through the upper-right quarter area LA2 of the lens, and the illumination light incident on the pixel 201d has passed through the upper-left quarter area LA1 of the lens. Thus, the actual observation values are given by Equation (13). Note that m_{rc}ⁿ in Equation (13) indicates an element in the r-th row and c-th column of a Mueller matrix Mn. Furthermore, each row of Equation (13) is independent, and there is no m_{rc}ⁿ that is common between rows.

$$\begin{matrix}[ Math . 10 ] & \\ [ \begin{matrix}{I}_{0}^{4} \\ {I}_{45}^{2} \\ {I}_{90}^{1} \\ {I}_{135}^{3}\end{matrix} ] = [ \begin{matrix}{m}_{00}^{4} + 0.5 {m}_{10}^{4} & {m}_{01}^{4} + 0.5 {m}_{11}^{4} & {{m}^{4}}_{02} + 0.5 {m}_{12}^{4} \\ {m}_{00}^{2} + 0.5 {m}_{20}^{2} & {m}_{01}^{2} + 0.5 {m}_{21}^{2} & {m}_{02}^{2} + 0.5 {m}_{22}^{2} \\ {m}_{00}^{1} - 0.5 {m}_{10}^{1} & {m}_{01}^{1} - 0.5 {m}_{11}^{1} & {m}_{02}^{1} - 0.5 {m}_{12}^{1} \\ {m}_{00}^{3} - 0.5 {m}_{20}^{3} & {m}_{01}^{3} - 0.5 {m}_{21}^{3} & {m}_{02}^{3} - 0.5 {m}_{22}^{3}\end{matrix} ] [ \begin{matrix}{S}_{0} \\ {S}_{1} \\ {S}_{2}\end{matrix} ] & ( 13 )\end{matrix}$$

For example, the observation value I₀⁴ of the pixel 201a can be calculated on the basis of Equation (14). Furthermore, when six sets of observation values I₀⁴ are obtained for the illumination light with the Stokes vector S, m_{rc}⁴ in Equation (14) can be calculated. In a similar manner, elements m_{rc}¹, m_{rc}², and mr_{c}³ are calculated, and then the Stokes vector S can be calculated on the basis of the observation values. That is, the elements m_{rc}¹, m_{rc}², m_{rc}³, and mr_{c}⁴ are calculated and used as a correction parameter P.

[Math. 11]

I₀⁴=(m₀₀⁴+0.5₁₀⁴)s₀+(m₀₁⁴+0.5m₁₁⁴)s₁+(m₀₂⁴+0.5m₁₂⁴)s₂ (14)

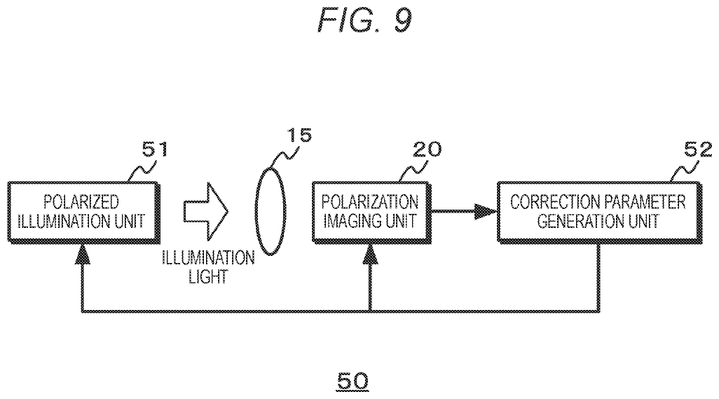

FIG. 9 illustrates a configuration of a calibration device that generates a correction parameter. A calibration device 50 includes the above-described main lens 15 and polarization imaging unit 20 used for acquiring a polarization image, a polarized illumination unit 51, and a correction parameter generation unit 52. The polarized illumination unit 51 emits, toward the main lens 15, linearly polarized light having a known polarization direction as illumination light. The polarization imaging unit 20 images the polarized illumination unit 51 by using the main lens 15 to acquire a polarization image. The correction parameter generation unit 52 controls the polarized illumination unit 51 to switch to illumination light with a different Stokes vector S and output the illumination light. Furthermore, the correction parameter generation unit 52 controls the polarization imaging unit 20 to acquire a polarization image at every switching of the illumination light output from the polarized illumination unit 51. Moreover, the correction parameter generation unit 52 uses the polarization images acquired one for each of a plurality of types of illumination light with different Stokes vectors S to generate a correction parameter for each microlens.

Specifically, the polarized illumination unit 51 is configured to switch between six types of linearly polarized light with different Stokes vectors S and emit the linearly polarized light as illumination light, and the correction parameter generation unit 52 causes the polarization imaging unit 20 to acquire a polarization image for each of the six types of illumination light with the different Stokes vectors S. On the basis of observation values of the captured images of the six types of illumination light with the different Stokes vectors S and the Stokes vectors S of the illumination light, the correction parameter generation unit 52 calculates the elements m_{rc}¹, m_{rc}², m_{rc}³, and m_{rc}⁴ and uses the elements as a correction parameter as described above.

Incidentally, in a case of a configuration illustrated in FIG. 7, refraction is the only factor that changes the polarization state when polarized light passes through the lens. A Mueller matrix M of refraction is given by Equation (15).

$$\begin{matrix}[ Math . 12 ] & \\ M = [ \begin{matrix}a & b & 0 \\ b & a & 0 \\ 0 & 0 & c\end{matrix} ] & ( 15 )\end{matrix}$$

Thus, using the Mueller matrix of refraction makes it easier to calculate a correction parameter. That is, when the Mueller matrix of refraction is used, Equation (11) described above is converted to Equation (16), and Equation (12) is converted to Equation (17). This makes it easier to calculate a correction parameter.

$$\begin{matrix}[ Math . 13 ] & \\ [ \begin{matrix}{I}_{0} \\ {I}_{45} \\ {I}_{90} \\ {I}_{135}\end{matrix} ] = B [ \begin{matrix}{S}_{0}^{′} \\ {S}_{1}^{′} \\ {S}_{2}^{′}\end{matrix} ] = B [ \begin{matrix}a & b & 0 \\ b & a & 0 \\ 0 & 0 & c\end{matrix} ] [ \begin{matrix}{S}_{0} \\ {S}_{1} \\ {S}_{2}\end{matrix} ] = [ \begin{matrix}a + 0.5 b & b + 0.5 a & 0 \\ a & b & 0.5 c \\ a - 0.5 b & b - 0.5 a & 0 \\ a & b & - 0.5\end{matrix} ] [ \begin{matrix}{S}_{0} \\ {S}_{1} \\ {S}_{2}\end{matrix} ] & ( 16 ) \\ [ \begin{matrix}{I}_{0}^{4} \\ {I}_{45}^{2} \\ {I}_{90}^{1} \\ {I}_{135}^{3}\end{matrix} ] = [ \begin{matrix}{a}^{4} + 0.5 {b}^{4} & {b}^{4} + 0.5 {a}^{4} & 0 \\ {a}^{2} & {b}^{2} & 0.5 {c}^{2} \\ {a}^{1} - 0.5 {b}^{1} & {b}^{1} - 0.5 {a}^{1} & 0 \\ {a}^{3} & {b}^{3} & - {0.5}^{3}\end{matrix} ] [ \begin{matrix}{S}_{0} \\ {S}_{1} \\ {S}_{2}\end{matrix} ] & ( 17 )\end{matrix}$$

In Equation (17), aⁿ, bⁿ, and cⁿ (n=1, 2, 3, or 4) are elements of the Mueller matrix corresponding to the portions of the lens. Furthermore, as is apparent from the above Equation (1) and FIG. 3, polarization characteristics have 180-degree symmetry, and the same change in polarization state occurs in optical systems having 180-degree symmetry. For this reason, the same Mueller matrix corresponds to the upper-left area LA1 and the lower-right area LA4 of the main lens, and the same Mueller matrix corresponds to the upper-right area LA2 and the lower-left area LA3. That is, “(a¹, b¹, c¹)=(a⁴, b⁴, c⁴)” and “(a², b², c²)=(a³, b³, c³)” are satisfied. Thus, two equations can be obtained from polarized light having one polarization direction. In this case, since there are five unknowns (for example, a¹, b¹, a², b², and c²) in Equation (17), a correction parameter can be generated by obtaining observation values of three types of illumination light with different Stokes vectors S.

Note that a pseudo inverse of a matrix of Equation (17) may be held in the correction parameter storage unit 32 so that the polarization state calculation unit 31 can calculate a Stokes vector S. Alternatively, only the five unknowns constituting the matrix may be held so that a pseudo inverse matrix can be calculated at the time of calculation of an actual polarization state. Moreover, correction parameters corresponding to all microlenses may be held, or correction parameters corresponding to some of microlenses may be held. In this case, for a microlens for which corresponding correction parameters are not stored, it is possible to perform, for example, interpolation processing using correction parameters of microlenses located in the surroundings and calculate a correction parameter.

<3-3. Second Embodiment of Information Processing Unit>

Next, a second embodiment of the information processing unit will be described. In the second embodiment, depth information is generated on the basis of a polarization image acquired by a polarization imaging unit 20. Furthermore, in a case where depth information is generated on the basis of a polarization image, a pixel group for each microlens in the polarization imaging unit includes a set of pixels having the same polarization characteristic.

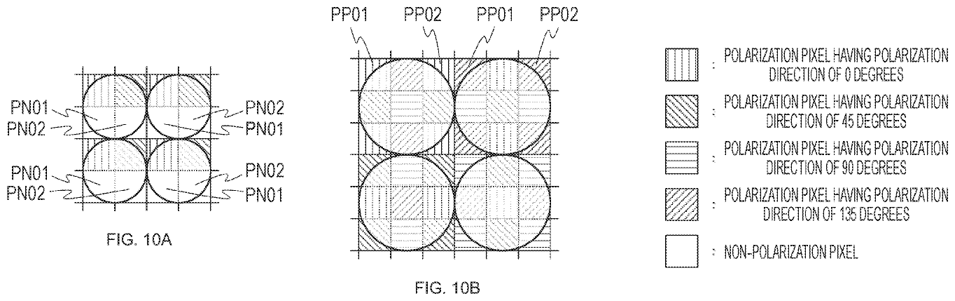

FIG. 10 illustrates a pixel arrangement that includes a set of pixels having the same polarization characteristic. (a) of FIG. 10 illustrates a case where a set of pixels having the same polarization characteristic is non-polarization pixels PN01 and PN02 in the same row. (b) of FIG. 10 illustrates a case where a pixel group is constituted by pixels in a two-dimensional area of n by n pixels (n is a natural number equal to or higher than 3), for example, pixels in a two-dimensional area of three by three pixels, and a set of pixels having the same polarization characteristic is polarization pixels PP01 and PP02 that have the same polarization direction and are one pixel away from each other in the same row. Note that the set of pixels having the same polarization characteristics is not limited to a set of polarization pixels that are one pixel away from each other in a middle row in the pixel group, and may be a set of polarization pixels in an upper row or a lower row. Furthermore, the set of pixels having the same polarization characteristic may be pixels in the same column.

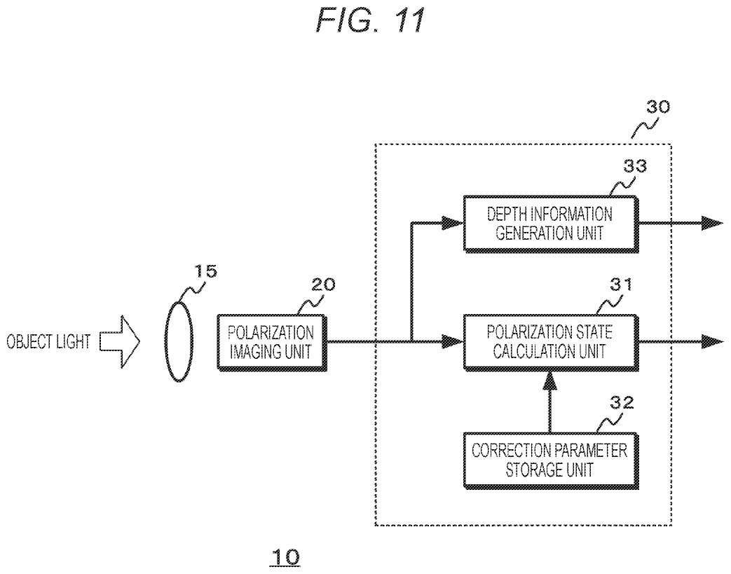

FIG. 11 illustrates a configuration of the second embodiment of the information processing unit. An information processing unit 30 includes a polarization state calculation unit 31, a correction parameter storage unit 32, and a depth information generation unit 33.

The polarization state calculation unit 31 and the correction parameter storage unit 32 have configurations similar to those in the first embodiment, and the polarization state calculation unit 31 calculates a polarization state of an object on the basis of polarization images having a plurality of polarization directions acquired by the polarization imaging unit 20. Furthermore, the polarization state calculation unit 31 uses a correction parameter stored in the correction parameter storage unit 32 to correct a change in polarization state caused by a lens in the polarization images, and calculates a polarization state of the object.

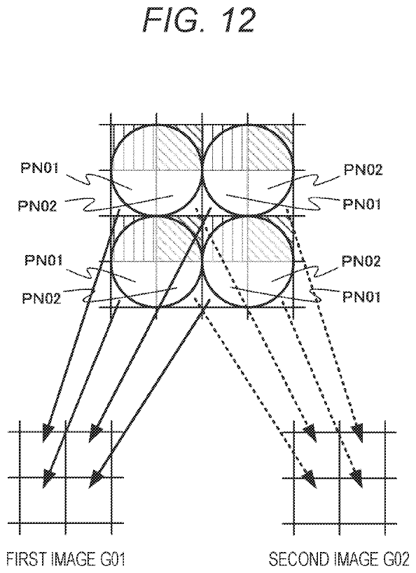

The depth information generation unit 33 generates a plurality of viewpoint images from the polarization images acquired by the polarization imaging unit 20, and calculates a distance to the object on the basis of the viewpoint images. FIG. 12 is a diagram for describing generation of a plurality of viewpoint images. The depth information generation unit 33 generates a first image using one of a set of pixels having the same polarization characteristic from each pixel group provided with a microlens, and generates a second image using the other pixel. The depth information generation unit 33 generates a first image G01 using, for example, the non-polarization pixel PN01, which is one of a set of pixels having the same polarization characteristic from each pixel group of two by two pixels, and generates a second image G02 using the non-polarization pixel PN02, which is the other of the set of pixels. Light incident on the non-polarization pixel PN01 and light incident on the non-polarization pixel PN02 have passed through different areas of a main lens 15 as described above, and the non-polarization pixel PN01 and the non-polarization pixel PN02 are pixels with different viewpoints. That is, the first image using one of the set of pixels having the same polarization characteristic from each pixel group and the second image using the other pixel correspond to two viewpoint images captured by a stereo camera. Thus, stereo matching processing is performed in a similar manner as before using the first image and the second image corresponding to the two viewpoint images captured by the stereo camera, the distance to the object (depth) is calculated, and depth information indicating the calculated distance is output.

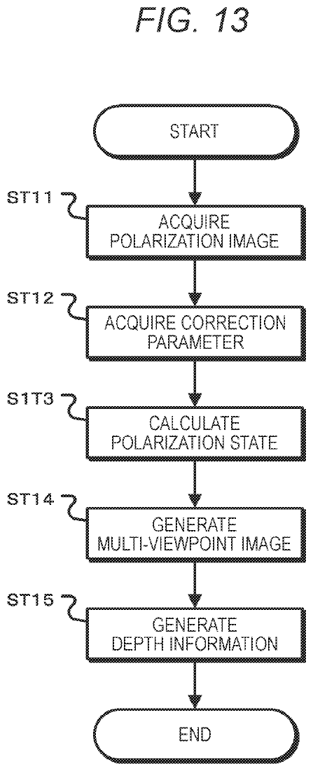

FIG. 13 is a flowchart illustrating operation of the second embodiment of the information processing unit. In step ST11, the information processing unit acquires a polarization image. The information processing unit 30 acquires a polarization image obtained by imaging a desired object with the polarization imaging unit 20 using the main lens 15, and the operation proceeds to step ST12.

In step ST12, the information processing unit acquires a correction parameter. The polarization state calculation unit 31 of the information processing unit 30 acquires, from the correction parameter storage unit 32, a correction parameter for each microlens 203 in accordance with the main lens 15, and the operation proceeds to step ST13.

In step ST13, the information processing unit calculates a polarization state. The polarization state calculation unit 31 calculates a Stokes vector S using an observation value of each pixel of a pixel group and the correction parameter corresponding to the microlens of the pixel group, and the operation proceeds to step ST14.

In step ST14, the information processing unit generates a multi-viewpoint image. The depth information generation unit 33 of the information processing unit 30 generates, as multi-viewpoint images, a first image using one of a set of pixels having the same polarization characteristic from each pixel group provided with a microlens and a second image using the other pixel, and then the operation proceeds to step ST15.

In step ST15, the information processing unit generates depth information. The depth information generation unit 33 performs stereo matching processing or the like using the multi-viewpoint images generated in step ST14, calculates a distance to the object, and generates depth information indicating the calculated distance.

Note that the operation of the second embodiment is not limited to the order illustrated in FIG. 13, as long as the processing of step ST12 is performed before the processing of step ST13, and the processing of step ST14 is performed before the processing of step ST15.

In this way, according to the second embodiment of the information processing unit, a change in polarization state caused by the lens that has occurred in a polarization image is corrected, and a polarization state of an object can be calculated more accurately than before. Furthermore, according to the second embodiment, depth information can be generated.

<3-4. Third Embodiment of Information Processing Unit>

Next, a third embodiment of the information processing unit will be described. In the third embodiment, more accurate depth information is generated than in the second embodiment.

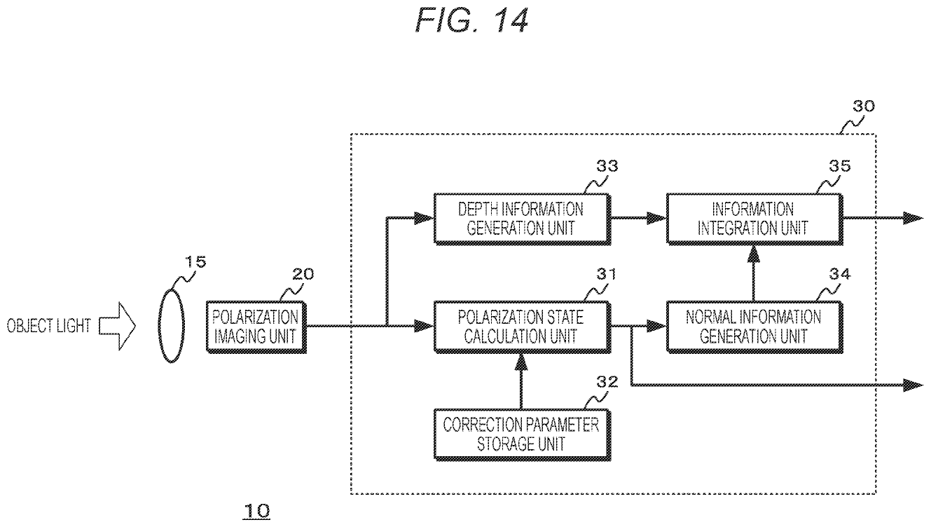

FIG. 14 illustrates a configuration of the third embodiment of the information processing unit. An information processing unit 30 includes a polarization state calculation unit 31, a correction parameter storage unit 32, a depth information generation unit 33, a normal information generation unit 34, and an information integration unit 35.

The polarization state calculation unit 31 and the correction parameter storage unit 32 have configurations similar to those in the first embodiment, and the polarization state calculation unit 31 calculates a polarization state of an object on the basis of polarization images having a plurality of polarization directions acquired by a polarization imaging unit 20. Furthermore, the polarization state calculation unit 31 uses a correction parameter stored in the correction parameter storage unit 32 to correct a change in polarization state caused by a lens in the polarization images, calculates a polarization state of the object, and outputs the calculated polarization state to the normal information generation unit 34.

The depth information generation unit 33, which has a configuration similar to that in the first embodiment, generates a plurality of viewpoint images from the polarization images acquired by the polarization imaging unit 20, calculates a distance to the object on the basis of the viewpoint images, and outputs, to the information integration unit 35, depth information indicating the calculated distance.

The normal information generation unit 34 calculates a normal to the object on the basis of the polarization state calculated by the polarization state calculation unit 31. Here, when the polarization direction of the polarization plate 42 illustrated in FIG. 2 is changed and a minimum luminance Imin and a maximum luminance Imax are obtained, a polarization degree p can be calculated on the basis of Equation (18). Furthermore, as shown in Equation (18), the polarization degree p can be calculated using a relative refractive index nᵣ of an object OB and a zenith angle θ, which is an angle from a z axis toward the normal. Note that the z-axis in this case is a line-of-sight axis that indicates a direction of a ray of light from an observation target point of the object OB toward an imaging unit 41.

$$\begin{matrix}[ Math . 14 ] & \\ ρ = \frac{{I}_{max} - {I}_{min}}{{I}_{max} + {I}_{min}} = \frac{( {n}_{r} - 1 / {n}_{r} ) {sin}^{2} θ}{2 + 2 {n}_{r}^{2} - {( {n}_{r} + 1 / {n}_{r} )}^{2} {sin}^{2} θ + 4 cos θ \sqrt{{n}_{r}^{2} - {sin}^{2} θ}} & ( 18 )\end{matrix}$$

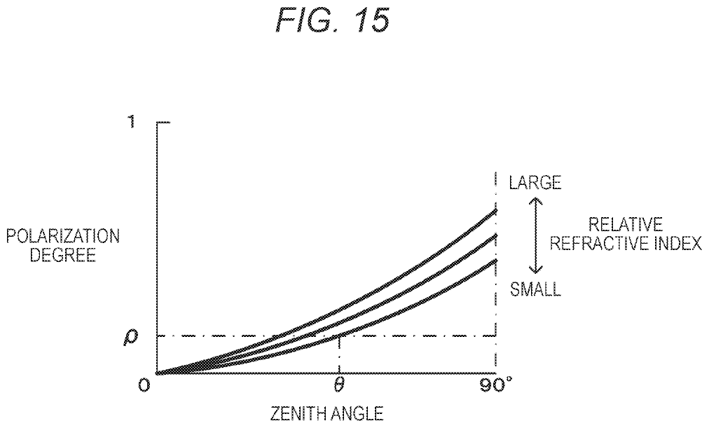

A relationship between a polarization degree and a zenith angle has, for example, a characteristic illustrated in FIG. 15, and this characteristic can be used to calculate the zenith angle θ on the basis of the polarization degree ρ. Note that, as is apparent from Equation (18), the characteristic illustrated in FIG. 15 depends on the relative refractive index nᵣ, and the polarization degree increases as the relative refractive index nᵣ increases.

Thus, the normal information generation unit 34 calculates the zenith angle θ on the basis of the polarization degree ρ calculated using Equation (18). Furthermore, normal information indicating the zenith angle θ and the azimuth angle φ is generated and output to the information integration unit 35, the azimuth angle φ being a polarization angle U when the maximum luminance Imax is observed.

The information integration unit 35 integrates the depth information generated by the depth information generation unit 33 and the normal information generated by the normal information generation unit 34, and generates depth information more accurate than a distance calculated by the depth information generation unit 33.

For example, in a case where a depth value has not been acquired in the depth information, on the basis of a surface shape of the object indicated by the normal information and a depth value indicated by the depth information, the information integration unit 35 traces the surface shape of the object starting from a pixel for which a depth value has been obtained. The information integration unit 35 traces the surface shape to calculate a depth value corresponding to a pixel for which a depth value has not been obtained. Furthermore, the information integration unit 35 includes the estimated depth value in the depth information generated by the depth information generation unit 33, thereby generating and outputting depth information having an accuracy equal to or higher than that of the depth information generated by the depth information generation unit 33.

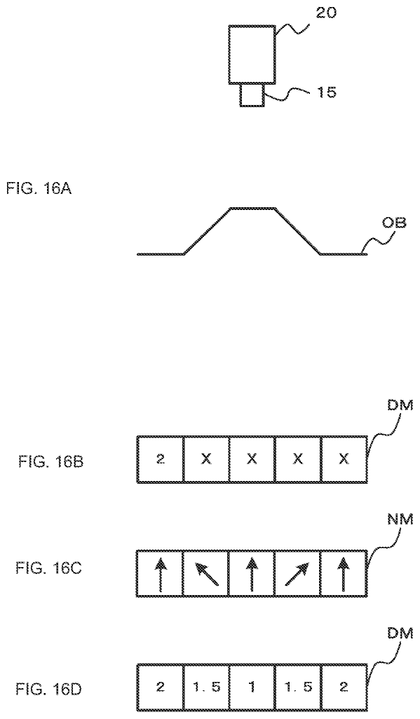

FIG. 16 is a diagram for describing information integration processing. Note that, for the sake of simplicity of description, integration processing for one line will be described as an example. It is assumed that, the object OB has been imaged as illustrated in (a) of FIG. 16, a depth value illustrated in (b) of FIG. 16 has been calculated by the depth information generation unit 33, and a normal illustrated in (c) of FIG. 16 has been calculated by the normal information generation unit 34. Furthermore, in depth information, it is assumed that, for example, a depth value for a leftmost pixel is “2 (meters)”, and depth values are not stored for other pixels indicated by “x”. The information integration unit 35 estimates the surface shape of the object OB on the basis of the normal information. Here, it can be determined on the basis of a normal direction of a second pixel from the left end that this pixel corresponds to a surface sloping from an object surface corresponding to the leftmost pixel in a direction toward the polarization imaging unit 20. Thus, the information integration unit 35 traces the surface shape of the object OB starting from the leftmost pixel, and estimates a depth value of the second pixel from the left end to be “1.5 (meters)”, for example. Furthermore, the information integration unit 35 stores the estimated depth value in the depth information. It can be determined on the basis of a normal direction of a third pixel from the left end that this pixel corresponds to a surface facing the polarization imaging unit 20. Thus, the information integration unit 35 traces the surface shape of the object OB starting from the leftmost pixel, and estimates a depth value of the third pixel from the left end to be “1 (meter)”, for example. Furthermore, the information integration unit 35 stores the estimated depth value in the depth information. It can be determined that a fourth pixel from the left end corresponds to a surface sloping from the object surface corresponding to the third pixel from the left end in a direction away from the polarization imaging unit 20. Thus, the information integration unit 35 traces the surface shape of the object OB starting from the leftmost pixel, and estimates a depth value of the fourth pixel from the left end to be “1.5 (meters)”, for example. Furthermore, the information integration unit 35 stores the estimated depth value in a depth map. In a similar manner, a depth value of a fifth pixel from the left end is estimated to be “2 (meters)”, for example, and stored in the depth map.

In this way, the information integration unit 35 integrates depth information and normal information, estimates a depth value by tracing a surface shape starting from a depth value indicated by the depth information on the basis of the normal information. Thus, even in a case where some of the depth values are missing from the depth information illustrated in (b) of FIG. 16 generated by the depth information generation unit 33, the information integration unit 35 can supplement the missing depth values. Thus, it is possible to generate the depth information illustrated in (d) of FIG. 16 having an accuracy equal to or higher than that of the depth information illustrated in (b) of FIG. 16.

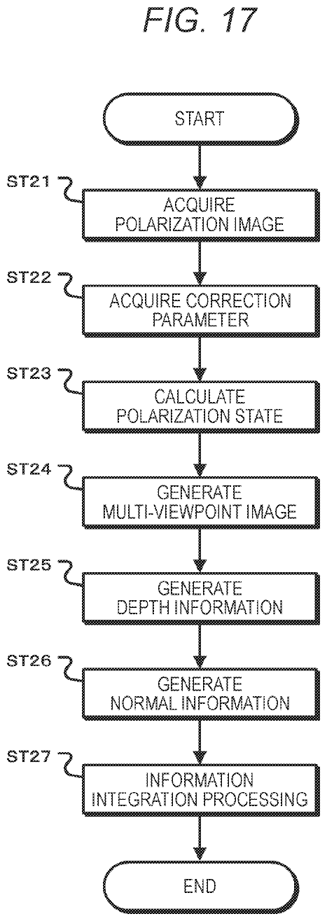

FIG. 17 is a flowchart illustrating operation of the third embodiment of the information processing unit. In step ST21, the information processing unit acquires a polarization image. The information processing unit 30 acquires a polarization image obtained by imaging a desired object with the polarization imaging unit 20 using a main lens 15, and the operation proceeds to step ST22.

In step ST22, the information processing unit acquires a correction parameter. The polarization state calculation unit 31 of the information processing unit 30 acquires, from the correction parameter storage unit 32, a correction parameter for each microlens 203 in accordance with the main lens 15, and the operation proceeds to step ST23.

In step ST23, the information processing unit calculates a polarization state. The polarization state calculation unit 31 calculates a Stokes vector S using an observation value of each pixel of a pixel group and the correction parameter corresponding to the microlens of the pixel group, and the operation proceeds to step ST24.

In step ST24, the information processing unit generates a multi-viewpoint image. The depth information generation unit 33 of the information processing unit 30 generates, as multi-viewpoint images, a first image using one of a set of pixels having the same polarization characteristic from each pixel group provided with a microlens and a second image using the other pixel, and then the operation proceeds to step ST25.

In step ST25, the information processing unit generates depth information. The depth information generation unit 33 performs stereo matching processing or the like using the multi-viewpoint images generated in step S24, calculates a distance to the object, and generates depth information indicating the calculated distance. Then, the operation proceeds to step ST26.

In step ST26, the information processing unit generates normal information. The normal information generation unit 34 of the information processing unit 30 calculates a zenith angle and an azimuth angle from the polarization state calculated in step ST23, and generates normal information indicating the calculated zenith angle and azimuth angle. Then, the operation proceeds to step ST27.

In step ST27, the information processing unit performs information integration processing. The information integration unit 35 of the information processing unit 30 integrates the depth information generated in step ST25 and the normal information generated in step ST26, and generates depth information more accurate than the depth information generated in step ST25.

Note that the operation of the third embodiment is not limited to the order illustrated in FIG. 17, as long as the processing of step ST22 is performed before the processing of step ST23, the processing of step ST23 is performed before the processing of step ST26, the processing of step ST24 is performed before the processing of step ST25, and the processing of steps ST25 and 26 is performed before the processing of step ST27.

In this way, according to the third embodiment of the information processing unit, a change in polarization state that occurs in the main lens is corrected, and a polarization state of an object can be calculated more accurately than before. Furthermore, it is possible to accurately generate normal information on the basis of the calculated polarization state of the object. Moreover, it is possible to generate accurate depth information by integrating the normal information and depth information generated on the basis of a polarization image acquired by the polarization imaging unit.

<3-5. Other Embodiments of Information Processing Unit>

In the second and third embodiments of the information processing unit, depth information is generated. Alternatively, the information processing unit may be configured to calculate a polarization state and generate normal information without generating depth information.

Furthermore, the information processing unit may be provided with an image processing unit, and the image processing unit may use a calculated polarization state to perform image processing of an image of an object such as adjustment or removal of a reflection component, for example. As described above, a Stokes vector S calculated by the polarization state calculation unit 31 is used to correct a change in polarization state that occurs in a main lens and indicate a polarization state of an object more accurately than before. Thus, the image processing unit computes Equation (8) using a Stokes vector S calculated by the polarization state calculation unit 31 and the matrix B shown in Equation (7), and obtains the polarization model equation of Equation (1) using a calculated observation value for each polarization direction. An amplitude of this polarization model equation indicates a specular reflection component, and a minimum value indicates a diffuse reflection component. This allows for, for example, accurate adjustment or removal of the specular reflection component on the basis of the Stokes vector S calculated by the polarization state calculation unit 31.

Furthermore, the polarization imaging unit 20 and the information processing unit 30 are not limited to a case where they are provided separately. Alternatively, the polarization imaging unit 20 and the information processing unit 30 may be integrally configured, in which a configuration of one of the polarization imaging unit 20 or the information processing unit 30 is included in the other.

### 4. Application Examples

The technology according to the present disclosure can be applied to a variety of fields. For example, the technology according to the present disclosure may be materialized as a device that is mounted on any type of mobile object such as an automobile, an electric vehicle, a hybrid electric vehicle, a motorcycle, a bicycle, personal mobility, an airplane, a drone, a ship, or a robot. Furthermore, the technology may be materialized as a device that is mounted on equipment used in a production process in a factory or equipment used in the construction field. When the technology is applied to such a field, a change in polarization state caused by the lens that occurs in polarization state information can be corrected, and it is possible to accurately perform generation of normal information, separation of reflection components, or the like on the basis of corrected polarization state information. Thus, a surrounding environment can be accurately grasped in three dimensions, and fatigue of a driver or a worker can be reduced. Furthermore, automatic driving and the like can be performed more safely.

The technology according to the present disclosure can also be applied to the medical field. For example, when the technology is applied to a case where a captured image of a surgical site is used during surgery, an image of a three-dimensional shape of the surgical site or an image without reflection can be accurately obtained. This reduces fatigue of an operator and enables safer and more reliable surgery.

Furthermore, the technology according to the present disclosure can be applied to fields such as public services. For example, when an image of an object is published in a book, a magazine, or the like, unnecessary reflection components and the like can be accurately removed from the image of the object.

The series of processing described in the specification can be executed by hardware, software, or a combination of both. In a case where the processing is executed by software, a program in which a processing sequence has been recorded is installed on a memory in a computer built in dedicated hardware, and then the program is executed. Alternatively, the program can be installed on a general-purpose computer capable of executing various types of processing and then executed.

For example, the program can be recorded in advance in a hard disk, a solid state drive (SSD), or a read only memory (ROM) as a recording medium. Alternatively, the program can be temporarily or permanently stored (recorded) in a removable recording medium such as a flexible disk, a compact disc read only memory (CD-ROM), a magneto optical (MO) disk, a digital versatile disc (DVD), a Blu-Ray Disc (registered trademark) (BD), a magnetic disk, or a semiconductor memory card. Such a removable recording medium can be provided as so-called package software.

Furthermore, the program may be installed on a computer from a removable recording medium, or may be wirelessly or wiredly transferred from a download site to a computer via a network such as a local area network (LAN) or the Internet. The computer can receive the program transferred in this way and install it on a recording medium such as a built-in hard disk.

Note that the effects described herein are merely illustrative and are not intended to be restrictive, and there may be additional effects that are not described. Furthermore, the present technology should not be construed as being limited to the embodiments of the technology described above. The embodiments of this technology disclose the present technology in the form of exemplification, and it is obvious that those skilled in the art may make modifications and substitutions to the embodiments without departing from the gist of the present technology. That is, in order to determine the gist of the present technology, the claims should be taken into consideration.

Furthermore, the solid-state imaging device of the present technology can also be configured as described below.

(1) A solid-state imaging device in which

each pixel group including a plurality of pixels is provided with a microlens,

the pixel group includes at least three polarization pixels having different polarization directions, and

the pixels included in the pixel group perform photoelectric conversion of light incident via the microlens.

(2) The solid-state imaging device according to (1), in which

the pixel group includes two pixels having the same polarization direction.

(3) The solid-state imaging device according to (2), in which

the pixel group includes pixels in a two-dimensional area of two by two pixels, and

the pixel group is constituted by a polarization pixel having a polarization direction at a specific angle, a polarization image having a polarization direction with an angular difference of 45 degrees from the specific angle, and two non-polarization pixels.

(4) The solid-state imaging device according to (2), in which

the pixel group includes pixels in a two-dimensional area of n by n pixels (n is a natural number equal to or higher than 3), and

polarization pixels that are at least one pixel away from each other have the same polarization direction.

(5) The solid-state imaging device according to any one of (1) to (4), in which

every one of the pixel groups is provided with a color filter, and

color filters of adjacent pixel groups differ in wavelength of light that is allowed to pass through.

### INDUSTRIAL APPLICABILITY

In the solid-state imaging device, the information processing device, the information processing method, and the calibration method of this technology, the solid-state imaging device has a configuration in which each pixel group including a plurality of pixels is provided with a microlens and the pixel group includes at least three polarization pixels having different polarization directions, and the pixels included in the pixel group perform photoelectric conversion of light that is incident via the microlenses. Furthermore, the information processing device uses a polarization image of an object acquired using the solid-state imaging device and a main lens, and a correction parameter set in advance for each microlens in accordance with the main lens, to calculate a polarization state of the object. Thus, a polarization state can be acquired accurately. For this reason, this technology is suitable for fields in which a surrounding environment is grasped in three dimensions, fields in which reflection components are adjusted, and the like.

### REFERENCE SIGNS LIST

10 System
15 Main lens
20 Polarization imaging unit
30 Information processing unit
31 Polarization state calculation unit
32 Correction parameter storage unit
33 Depth information generation unit
34 Normal information generation unit
35 Information integration unit
41 Imaging unit
42 Polarization plate
50 Calibration device
51 Polarized illumination unit
52 Correction parameter generation unit
201a to 201f Pixel
202a to 202d Polarizer
203 Microlens

1. A solid-state imaging device wherein
each pixel group including a plurality of pixels is provided with a microlens,
the pixel group includes at least three polarization pixels having different polarization directions, and
the pixels included in the pixel group perform photoelectric conversion of light incident via the microlens.

2. The solid-state imaging device according to claim 1, wherein
the pixel group includes two pixels having the same polarization direction.

3. The solid-state imaging device according to claim 2, wherein
the pixel group includes pixels in a two-dimensional area of two by two pixels, and
the pixel group is constituted by a polarization pixel having a polarization direction at a specific angle, a polarization image having a polarization direction with an angular difference of 45 degrees from the specific angle, and two non-polarization pixels.

4. The solid-state imaging device according to claim 2, wherein
the pixel group includes pixels in a two-dimensional area of n by n pixels (n is a natural number equal to or higher than 3), and
polarization pixels that are at least one pixel away from each other have the same polarization direction.

5. The solid-state imaging device according to claim 1, wherein
every one of the pixel groups is provided with a color filter, and
color filters of adjacent pixel groups differ in wavelength of light that is allowed to pass through.

6. An information processing device comprising
a polarization state calculation unit that calculates a polarization state of an object by using a polarization image of the object acquired by using a main lens and a solid-state imaging device provided with a microlens for each pixel group including at least three polarization pixels having different polarization directions, and a correction parameter set in advance for each microlens in accordance with the main lens.

7. The information processing device according to claim 6, further comprising
a depth information generation unit that generates a multi-viewpoint image from the polarization image and generates depth information indicating a distance to the object on a basis of the multi-viewpoint image.

8. The information processing device according to claim 7, further comprising:
a normal information generation unit that generates normal information indicating a normal to the object on a basis of the polarization state of the object calculated by the polarization state calculation unit; and
an information integration unit that generates depth information more accurate than the depth information generated by the depth information generation unit on a basis of the normal information generated by the normal information generation unit.

9. The information processing device according to claim 7, wherein
the pixel group includes two pixels having the same polarization direction, and
the depth information generation unit generates one viewpoint image using one of the pixels having the same polarization direction in every one of the pixel groups, generates another viewpoint image using another of the pixels having the same polarization direction in every one of the pixel groups, and generates depth information indicating a distance to the object on a basis of the one viewpoint image and the another viewpoint image.

10. The information processing device according to claim 7, further comprising
a normal information generation unit that generates normal information indicating a normal to the object on a basis of the polarization state of the object calculated by the polarization state calculation unit.

11. An information processing method comprising
calculating, by a polarization state calculation unit, a polarization state of an object, by using a polarization image of the object acquired by using a main lens and a solid-state imaging device provided with a microlens for each pixel group including at least three polarization pixels having different polarization directions, and a correction parameter set in advance for each microlens in accordance with the main lens.

12. A calibration method comprising
generating, by a correction parameter generation unit, a correction parameter for correcting a polarization state of a light source calculated on a basis of a polarization image obtained by imaging the light source in a known polarization state by using a main lens and a solid-state imaging device provided with a microlens for each pixel group including at least three polarization pixels having different polarization directions, to the known polarization state of the light source.

13. The calibration method according to claim 12, wherein
the correction parameter generation unit controls switching of the polarization state of the light source and imaging of the solid-state imaging device to cause the solid-state imaging device to acquire a polarization image for every one of a plurality of the polarization states, and the correction parameter is generated on a basis of the acquired polarization images.
